(19) United States
(12) Patent Application Publication
(10) Pub. No.: US 2025/0301865 A1
(43) Pub. Date: Sep. 25, 2025

(54) DISPLAY PANEL AND DISPLAY DEVICE

(71) Applicant: HEFEI VISIONOX TECHNOLOGY CO., LTD., Hefei, Anhui (CN)

(72) Inventors: Jinfang ZHANG, Kunshan (CN); Zhiwei ZHOU, Kunshan (CN); Chung-chun LEE, Kunshan (CN)

(73) Assignees: HEFEI VISIONOX TECHNOLOGY CO., LTD., Hefei, Anhui (CN); VISIONOX TECHNOLOGY INC., Suzhou, Jiangsu (CN)

(21) Appl. No.: 18/758,341

(22) Filed: Jun. 28, 2024

(30) Foreign Application Priority Data
Mar. 21, 2024 (CN) 202410337686.7

(51) Int. Cl. H10K 59/131; H10K 59/122; H10K 59/35

(52) U.S. Cl. CPC H10K 59/131; H10K 59/122; H10K 59/35

(57) ABSTRACT

A display panel and a display device. The display panel includes a substrate, a pixel definition layer, and conductive layers. The pixel definition layer is located on one side of the substrate. The pixel definition layer includes multiple first light-transmissive openings that define pixel units. The conductive layers are disposed between the substrate and the pixel definition layer. The conductive layers include a first wire. Overlapping positions between the vertical projection of the first wire on the substrate and vertical projections of at least part of the first light-transmissive openings on the substrate are different. An overlapping position is the position of an overlapping portion between the vertical projection of the first wire on the substrate and the vertical projection of a first light-transmissive opening on the substrate relative to the vertical projection of the first light-transmissive opening on the substrate.

### CROSS-REFERENCE TO RELATED APPLICATION(S)

This application claims the priority of a Chinese Patent Application No. 202410337686.7, filed on Mar. 21, 2024, the disclosure of which is incorporated herein by reference in its entirety.

### TECHNICAL FIELD

Embodiments of the present application relate to the field of display technologies, particularly a display panel and a display device.

### BACKGROUND

With the development of display technologies, people increasingly require a good display quality.

However, an existing display panel is prone to have a poor display effect, limiting application of the display panel.

### SUMMARY

Some embodiments of the present application provide a display panel and a display device.

According to an aspect of the present application, a display panel is provided. The display panel includes a substrate, a pixel definition layer, and conductive layers. The pixel definition layer is located on one side of the substrate. The pixel definition layer includes a plurality of first light-transmissive openings that define pixel units. The conductive layers are disposed between the substrate and the pixel definition layer.

The conductive layers include a first wire. Overlapping positions between the vertical projection of the first wire on the substrate and vertical projections of at least part of the first light-transmissive openings on the substrate are different. An overlapping position of the overlapping positions is the position of an overlapping portion relative to a vertical projection of a corresponding first light-transmissive opening on the substrate, the overlapping portion is an overlap between the vertical projection of the first wire on the substrate and the vertical projection of the corresponding first light-transmissive opening on the substrate.

According to another aspect of the present application, a display panel is provided. The display panel includes a substrate, a pixel definition layer, and conductive layers. The pixel definition layer is located on one side of the substrate. The pixel definition layer includes a plurality of first light-transmissive openings that define pixel units. The conductive layers are disposed between the substrate and the pixel definition layer.

The conductive layers include a first wire and a second wire that are disposed in a same conductive layer. At least one of following configurations is satisfied: the vertical projection of the first wire on the substrate being located on a central axis of a vertical projection of a first light-transmissive opening in at least part of the first light-transmissive openings on the substrate; and the vertical projection of the first wire on the substrate and the vertical projection of the second wire on the substrate being located on the two sides of a central axis of a vertical projection of a first light-transmissive opening in at least part of the first light-transmissive openings on the substrate.

According to another aspect of the present application, a display panel is provided. The display panel includes a substrate, isolation structures, and conductive layers. The isolation structures are located on one side of the substrate. The isolation structures include second light-transmissive openings. The second light-transmissive openings are in one-to-one correspondence with pixel units. The conductive layers are disposed between the substrate and the isolation structures.

The conductive layers include a first wire and a second wire. At least one of following configurations is satisfied: the vertical projection of the first wire on the substrate being located on a central axis of a vertical projection of a second light-transmissive opening in at least part of the second light-transmissive openings on the substrate; and the vertical projection of the first wire on the substrate and the vertical projection of the second wire on the substrate being located on the two sides of a central axis of a vertical projection of a second light-transmissive opening in at least part of the second light-transmissive openings on the substrate.

According to another aspect of the present application, a display device is provided. The display device includes a display panel of any embodiment of the present application.

### BRIEF DESCRIPTION OF DRAWINGS

FIG. 1 is a plane view of a display panel according to an embodiment of the present application.

FIG. 2 is a section view of a display panel according to an embodiment of the present application.

FIG. 3 is a section view of another display panel according to an embodiment of the present application.

FIG. 4 is a plane view of another display panel according to an embodiment of the present application.

FIG. 5 is a pixel circuit diagram according to an embodiment of the present application.

FIG. 6 is a plane view of another display panel according to an embodiment of the present application.

FIG. 7 is a section view of another display panel according to an embodiment of the present application.

FIG. 8 is a section view of another display panel according to an embodiment of the present application.

FIG. 9 is a section view of another display panel according to an embodiment of the present application.

FIG. 10 is a section view of another display panel according to an embodiment of the present application.

FIG. 11 is a diagram illustrating the structure of a display device according to an embodiment of the present application.

### DETAILED DESCRIPTION

An existing display panel has a poor display effect. After careful research by the inventors, it is found that this problem occurs for the following reasons. In a sample display panel that uses a pixel-level encapsulation solution, the light-emitting function layer of each light-emitting element may be prepared by photolithography. Because fine masks are canceled, it is feasible to increase the opening ratio by reducing the gap (width between adjacent pixel areas) of the pixel definition layer of sample display panel. As the pixel opening ratio increases, the same film under a pixel opening is asymmetric. This causes a height difference in a light-emitting function layer formed later, and the pixel area (light-emitting area) has a poor flatness. As a result, color cast occurs in different viewing angles, affecting the display effect.

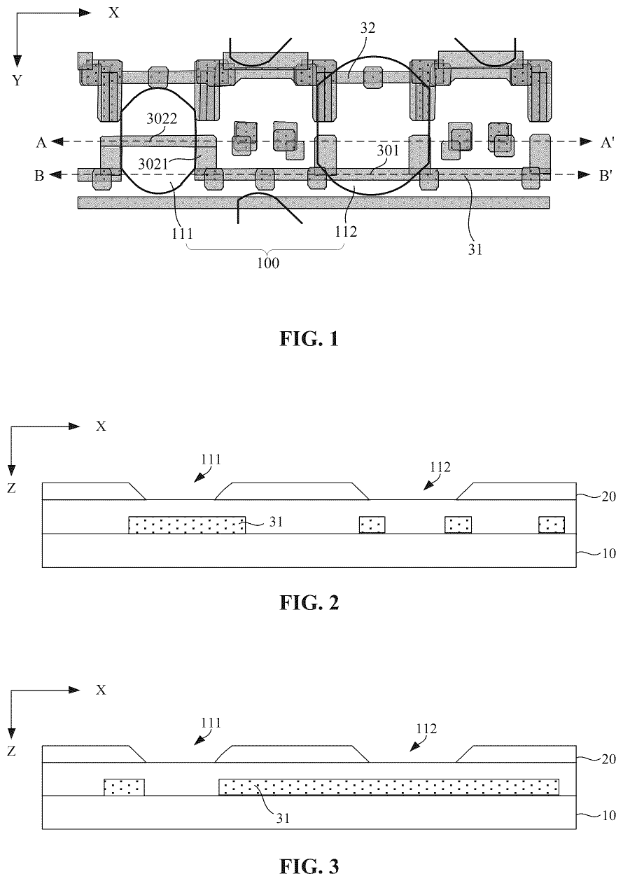

One or more embodiments of the present application provide a display panel to solve the problem of color cast. FIG. 1 is a plane view of a display panel according to an embodiment of the present application. FIG. 2 is a section view of a display panel according to an embodiment of the present application. FIG. 3 is a section view of another display panel according to an embodiment of the present application. FIG. 3 is a section view taken along BB′ of the display panel of FIG. 1.

Referring to FIG. 1 to FIG. 3, the display panel of some embodiments includes a substrate 10, a pixel definition layer 20, and multiple conductive layers. The pixel definition layer 20 is located on one side of the substrate 10. The pixel definition layer 20 includes multiple first light-transmissive openings 100 that define pixel units. The multiple conductive layers are disposed between the substrate 10 and the pixel definition layer 20.

The conductive layer includes one or more first wires 31. Overlapping positions between the vertical projection of a first wire 31 on the substrate 10 and vertical projections of at least part of the first light-transmissive openings 100 on the substrate 10 are different. An overlapping position is the position of an overlapping portion relative to a vertical projection of a corresponding first light-transmissive opening 100 on the substrate 10 and the overlapping portion is an overlap between the vertical projection of the first wire 31 on the substrate 10 and the vertical projection of the corresponding first light-transmissive opening 100 on the substrate 10.

Illustratively, the substrate 10 may be a rigid substrate such as a glass substrate or may be a flexible substrate such as a polyimide (PI) substrate. A pixel circuit array is disposed on the substrate 10. The pixel circuit array is configured to drive light-emitting elements to display.

Multiple conductive layers are formed on the substrate 10. Different wires are formed in the multiple conductive layers to transmit signals to the pixel circuit array. The pixel definition layer 20 is formed on the side of the multiple conductive layers facing away from the substrate 10. The pixel definition layer 20 includes multiple first light-transmissive openings 100 that define pixel units. Each first light-transmissive opening 100 corresponds to a pixel area including a pixel unit. Pixel units include different types of subpixels. Each subpixel corresponds to a first light-transmissive opening 100. For example, first light-transmissive openings 100 including two types of subpixels include the first light-transmissive opening 111 of a first subpixel and the first light-transmissive opening 112 of a second subpixel.

The conductive layer includes one or more first wires 31. Each first wire 31 is configured to transmit a voltage to a pixel area. With the original pixel opening ratio, there may be no first wire 31 under each first light-transmissive opening 100, so the conductive layer where the first wire 31 is located does not affect the flatness of a pixel area corresponding to a first light-transmissive opening 100. However, as the pixel opening ratio gradually increases, the area where a first light-transmissive opening 100 is located includes the area where an original first wire 31 is located. In this case, the first wire 31 causes a height difference in the pixel area corresponding to the first light-transmissive opening 100. Thus, when a light-emitting function layer is formed later by deposition, color cast is prone to occur during display, especially display at a large viewing angle.

In some embodiments, cabling of first wires 31 is optimized. Overlapping positions between the vertical projection of a first wire 31 on the substrate 10 and vertical projections of at least part of the first light-transmissive openings 100 on the substrate 10 are different, where an overlapping position is the position of an overlapping portion relative to a vertical projection of a corresponding first light-transmissive opening 100 on the substrate 10, and the overlapping portion is an overlap between the vertical projection of the first wire 31 on the substrate 10 and the vertical projection of the corresponding first light-transmissive opening 100 on the substrate 10. For example, the overlapping position between the vertical projection of a first wire 31 on the substrate 10 and the vertical projection of the corresponding first light-transmissive opening 111 of the first subpixel on the substrate 10 is in the middle of the vertical projection of the corresponding first light-transmissive opening 111 of the first subpixel on the substrate 10; and the overlapping position between the vertical projection of a first wire 31 on the substrate 10 and the vertical projection of the corresponding first light-transmissive opening 112 of the second subpixel on the substrate 10 is at the edge of the vertical projection of the corresponding first light-transmissive opening 112 of the second subpixel on the substrate 10. The vertical projection of a first light-transmissive opening 100 on the substrate 10 refers to the vertical projection of the area where the first light-transmissive opening 100 is located on the substrate 10. Generally, the pixel units are arrayed on the substrate 10. In the extension direction (for example, direction X) of the first wires 31, the same first wire 31 passes through different positions of at least part of the pixel areas. For example, as shown in FIG. 2, at the position of cutting line AA′, there is a through first wire 31 under the first light-transmissive opening 111 of a first subpixel, and there is no through first wire 31 under the first light-transmissive opening 112 of a second subpixel. As shown in FIG. 3, at the position of cutting line BB′, there is no through first wire 31 under the first light-transmissive opening 111 of a first subpixel, and there is a through first wire 31 under the first light-transmissive opening 112 of a second subpixel. That is, a first wire 31 is no longer a straight line, but a line that differs in different pixel areas so that the conductive layer where the first wire 31 is located is symmetrical in at least part of the pixel areas so that a film flatness difference in each pixel area is reduced such that the film height difference between the left part and the right part of each pixel area and/or the film height difference between the upper part and the lower part of each pixel area is small so that color cast at a non-front viewing angle is reduced.

In solutions of embodiments of the present application, positions of overlapping portions between vertical projection of a first wire 31 on the substrate 10 and vertical projections of at least part of the first light-transmissive openings 100 on the substrate 10 relative to vertical projections of the at least part of the first light-transmissive openings 100 on the substrate 10 are different. In this manner, the first wire 31 is differentiated under different first light-transmissive openings 100 so that the first wire 31 is symmetric under the at least part of the first light-transmissive openings 100. Thus, the solutions can reduce a film flatness difference in a pixel area, thereby alleviating the problem of display color cast and improving the display effect.

Optionally, the first wire 31 includes a metal wire.

Referring to FIG. 1, optionally, the first wire 31 includes a body portion 301 and a branch portion. The branch portion includes a first connection subportion 3021 and a second connection subportion 3022. The second connection subportion 3022 is connected to the body portion 301 by the first connection subportion 3021. The body portion 301 and the second connection subportion 3022 extend in a first direction X. The first connection subportion 3021 extends in a second direction Y intersecting the first direction X. The first direction X and the second direction Y are perpendicular to the thickness direction of the substrate 10.

Optionally, the pixel units include different types of subpixels, and overlapping positions between the vertical projection of a first wire 31 on the substrate 10 and vertical projections of first light-transmissive openings 100 corresponding to different types of subpixels on the substrate 10 are different. Optionally, sizes of the first light-transmissive openings 100 corresponding to the different types of subpixels are different. For example, the size of the first light-transmissive opening 111 of a first subpixel is less than the size of the first light-transmissive opening 112 of a second subpixel so that no other wire in the conductive layer where a first wire 31 is located is located under the first light-transmissive opening 111 of the first subpixel and other wires in the conductive layer where the first wire 31 is located are located under the first light-transmissive opening 112 of the second subpixel because the first light-transmissive opening 112 of the second subpixel is relatively large. Therefore, at the relatively small first light-transmissive opening 111 of the first subpixel, a branch of the first wire 31 moves in the second direction Y so that the vertical projection of the second connection subportion 3022 on the substrate 10 overlaps the central area of the vertical projection of a first light-transmissive opening 100 on the substrate 10; and cabling of the body portion 301 of the first wire 31 may remain unchanged, and the vertical projection of the body portion 301 on the substrate 10 overlaps the edge areas of the vertical projections of part of the first light-transmissive openings 100 on the substrate 10. The central area may be an area where the central axis of the first light-transmissive opening 100 in the first direction is located. That is, the second connection subportion 3022 and the central axis of the first light-transmissive opening 100 in the first direction are located in the same straight line. The edge area may be opposite sides of the central area. For example, the vertical projection of the first wire 31 on the substrate 10 is located on one side of the central axis of the vertical projection of the first light-transmissive opening 112 on the substrate 10. In this manner, the second connection subportion 3022 of the first wire 31 is located under the central area of the first light-transmissive opening 111 of the first subpixel, and the first light-transmissive opening 111 of the first subpixel is symmetrical about the second connection subportion 3022; thus, height differences formed after forming the light-emitting function layer are also symmetrical so that the problem of display color cast can be alleviated. The body portion 301 of the first wire 31 is located under the edge area of the first light-transmissive opening 112 of the second subpixel. The body portion 301 may be configured to be symmetrical to other wires in the conductive layer where the body portion 301 is located so that the problem of display color cast can be alleviated.

In other embodiments, if no wire other than the first wire 31 is located under the first light-transmissive opening 112 of the second subpixel, the first wire 31 may be cabled in the central area of the first light-transmissive opening 112 of the second subpixel so that the first light-transmissive opening 112 of the second subpixel is symmetrical about the first wire 31.

In some alternative embodiments, the vertical projection of the body portion 301 on the substrate 10 overlaps the central area of the vertical projection of the first light-transmissive opening 100 on the substrate 10; and cabling of the second connection subportion 3022 of the first wire 31 may remain unchanged, and the vertical projection of the second connection subportion 3022 on the substrate 10 overlaps the edge areas of the vertical projections of part of the first light-transmissive openings 100 on the substrate 10. This configuration has the same beneficial effects as the solution of the previous embodiments.

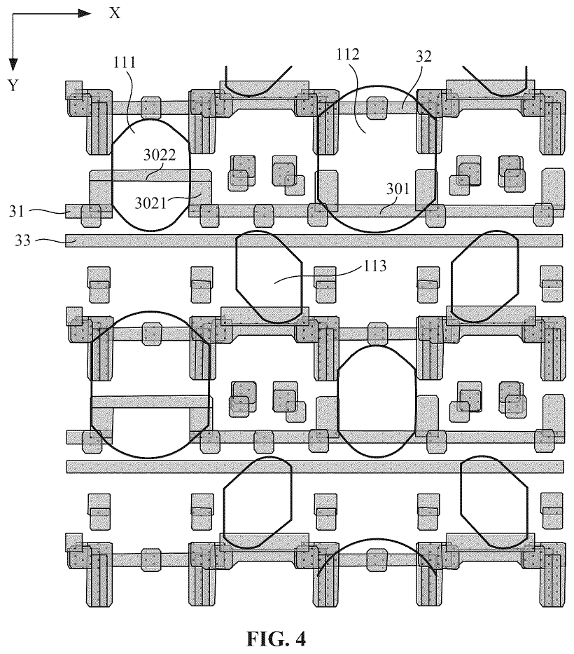

FIG. 4 is a plane view of another display panel according to an embodiment of the present application. Referring to FIG. 4, based on each previous embodiment, optionally, the pixel units include one or more first subpixels and one or more second subpixels. Each first subpixel and each second subpixel have different emission colors. For example, the first subpixels may be red subpixels, and the second subpixels may be blue subpixels. The first subpixels and the second subpixels are arrayed on the substrate 10. In the extension direction (first direction X) of the first wire 31, the first subpixels alternate with the second subpixels. The vertical projection of the first wire 31 on the substrate 10 overlaps the central area of the vertical projection of the first light-transmissive opening 111 of the first subpixel on the substrate 10. The vertical projection of the first wire 31 on the substrate 10 overlaps the edge area of the vertical projection of the first light-transmissive opening 112 of the second subpixel on the substrate 10.

Optionally, the pixel units also include third subpixels. The third subpixels may be green subpixels. The third subpixels are arranged in a row separate from other subpixels. No first wire 31 is located under the first light-transmissive opening 113 of a third subpixel. That is, the vertical projection of a first wire 31 on the substrate 10 does not overlap the vertical projection of the first light-transmissive opening 113 of a third subpixel on the substrate 10.

It is to be noted that the preceding arrangement of the first subpixels, the second subpixels, and the third subpixels are illustrative according to some embodiments. In other embodiments, a first wire 31 may be located under a third subpixel. In this case, the first wire 31 may be cabled in the preceding manner such that wires in the conductive layer where the first wire 31 under the first light-transmissive opening 113 of the third subpixel is located are symmetrical.

In some embodiments, the opening size of the first light-transmissive opening 112 of a second subpixel is greater than the opening size of the first light-transmissive opening 111 of a first subpixel, and the opening size of the first light-transmissive opening 111 of a first subpixel is greater than the opening size of the first light-transmissive opening 113 of a third subpixel. The opening size may be the opening area of a subpixel.

Referring to FIG. 4, the conductive layers also include one or more second wires 32. The second wires 32 and the first wires 31 are disposed in the same conductive layer. The vertical projection of a second wire 32 on the substrate 10 overlaps the edge area of the vertical projection of the first light-transmissive opening 112 of a second subpixel on the substrate 10. The vertical projection of a second wire 32 on the substrate 10 and the vertical projection of a first wire 31 on the substrate 10 are located on the two sides of the central axis of the vertical projection of the first light-transmissive opening 112 of a second subpixel on the substrate 10.

The extension direction of the second wires 32 is the same as the extension direction of the first wires 31. A second wire 32 and the body portion 301 of a first wire 31 are located under the edge area of the first light-transmissive opening 112 of a second subpixel. The second wire 32 and the body portion 301 of the first wire 31 are located on the two sides of the central axis of the vertical projection of the first light-transmissive opening 112 of the second subpixel on the substrate 10. Illustratively, the vertical projection of the body portion 301 of the first wire 31 on the substrate 10 and the vertical projection of the second wire 32 on the substrate 10 are symmetrical about the X-direction central axis of the vertical projection of the first light-transmissive opening 112 of the second subpixel on the substrate 10, thereby reducing a film flatness difference under the first light-transmissive opening 112 of the second subpixel and thus reducing color cast. Here the second wire 32 and the first wire 31 are different types of wires for transmitting different voltage signals. The central axis refers to a straight line that can divide the first light-transmissive opening 100 along a certain direction into two parts that cover the same area.

Optionally, on the two sides of the central axis of the vertical projection of the first light-transmissive opening 112 of a second subpixel, the overlapping area between the vertical projection of a first wire 31 on the substrate 10 and the vertical projection of the first light-transmissive opening 112 of the second subpixel on the substrate 10 and the overlapping area between the vertical projection of a second wire 32 on the substrate 10 and the vertical projection of the first light-transmissive opening 112 of the second subpixel on the substrate 10 are the same so that the height difference at the first wire 31 and the height difference at the second wire 32 are similar under the first light-transmissive opening 112 of the second subpixel, thereby reducing a film flatness difference under the first light-transmissive opening 112 of the second subpixel and thus reducing color cast.

Optionally, the shortest distance between the vertical projection of the first wire 31 on the substrate 10 and the central axis of the vertical projection of the first light-transmissive opening 112 of the second subpixel on the substrate 10 is the same as the shortest distance between the vertical projection of the second wire 32 on the substrate 10 and the central axis of the vertical projection of the first light-transmissive opening 112 of the second subpixel on the substrate 10. The first wire 31 and the second wire 32 are cabled as straight lines, and the shortest distance between the vertical projection of the first wire 31 on the substrate 10 and the central axis of the vertical projection of the first light-transmissive opening 112 of the second subpixel on the substrate 10 is the same as the shortest distance between the vertical projection of the second wire 32 on the substrate 10 and the central axis of the vertical projection of the first light-transmissive opening 112 of the second subpixel on the substrate 10 so that the vertical projection of the first wire 31 on the substrate 10 and the vertical projection of the second wire 32 on the substrate 10 are symmetrical about the X-direction central axis of the vertical projection of the first light-transmissive opening 112 of the second subpixel on the substrate 10, thereby reducing a film flatness difference under the first light-transmissive opening 112 of the second subpixel and thus reducing color cast.

It is to be noted that the same area or the same distance in some embodiments is not the completely same area or the completely same distance, but the roughly same area or the roughly same distance whose error is within an allowed range. For example, a first distance that is 0.9 to 1.1 times of a second distance is considered the same as the second distance, and a first area that is 0.9 to 1.1 times of a second area is considered the same as the second area.

Optionally, the conductive layers also include one or more third wires 33. The vertical projection of a third wire 33 on the substrate 10 and the vertical projection of a second wire 32 on the substrate 10 are located on the two sides of the central axis of the vertical projection of the first light-transmissive opening 113 of a third subpixel on the substrate 10. The third wires 33 are disposed in the same layer as the first wires 31 and the second wires 32. The extension direction of the third wires 33 is the same as the extension direction of the second wires 32. Each third wire 33 may be an in-plane fan-out wire for in-plane signal transmission. Under the first light-transmissive opening 113 of the third subpixel, the vertical projection of the second wire 32 on the substrate 10 and the vertical projection of the third wire 33 on the substrate 10 are symmetrical about the central axis of the vertical projection of the first light-transmissive opening 113 of the third subpixel on the substrate 10.

Optionally, on the two sides of the central axis of the vertical projection of the first light-transmissive opening 113 of a third subpixel, the overlapping area between the vertical projection of a second wire 32 on the substrate 10 and the vertical projection of the first light-transmissive opening 113 of the third subpixel on the substrate 10 and the overlapping area between the vertical projection of a third wire 33 on the substrate 10 and the vertical projection of the first light-transmissive opening 113 of the third subpixel on the substrate 10 are the same. Optionally, the shortest distance between the vertical projection of the second wire 32 on the substrate 10 and the central axis of the vertical projection of the first light-transmissive opening 113 of the third subpixel on the substrate 10 is the same as the shortest distance between the vertical projection of the third wire 33 on the substrate 10 and the central axis of the vertical projection of the first light-transmissive opening 113 of the third subpixel on the substrate 10. For details, see description about the first wires 31 and the second wires 32.

In some embodiments, overlapping positions between the vertical projection of a first wire 31 on the substrate 10 and vertical projections of first light-transmissive openings 100 corresponding to the same type of subpixels on the substrate 10 are the same. That is, on the substrate 10, the overlapping position between the vertical projection of a first wire 31 on the substrate 10 and the vertical projection of the first light-transmissive opening 111 of each first subpixel on the substrate 10 is located at the central area of the vertical projection of the first light-transmissive opening 111 of the each first subpixel on the substrate 10; and the overlapping position between the vertical projection of a first wire 31 on the substrate 10 and the vertical projection of the first light-transmissive opening 112 of each second subpixel on the substrate 10 is located at the edge area of the vertical projection of the first light-transmissive opening 112 of the each second subpixel on the substrate 10. Similarly, overlapping positions between the vertical projection of a second wire 32 on the substrate 10 and vertical projections of first light-transmissive openings 112 of second subpixels on the substrate 10 are the same; overlapping positions between the vertical projection of a second wire 32 on the substrate 10 and vertical projections of first light-transmissive openings 113 of third subpixels on the substrate 10 are the same; and overlapping positions between the vertical projection of a third wire 33 on the substrate 10 and vertical projections of first light-transmissive openings 113 of third subpixels on the substrate 10 are the same. Therefore, under each pixel area of the display panel, the conductive layer where the first wire 31 is located is symmetrical about the corresponding first light-transmissive opening 100. In this manner, film height differences are consistent under first light-transmissive openings 100 of the same type of subpixels so that during display, especially display at a large viewing angle, brightness is consistent at the same viewing angle, and color cast is reduced.

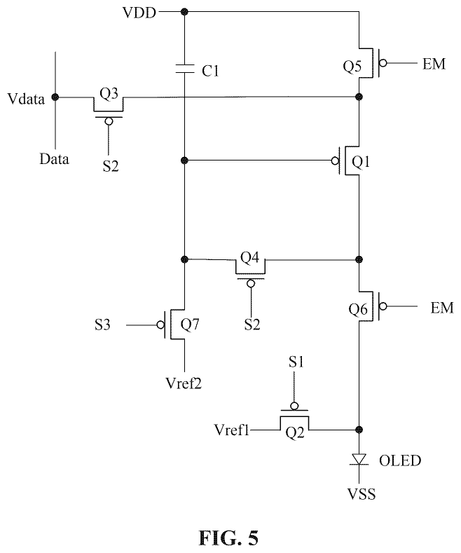

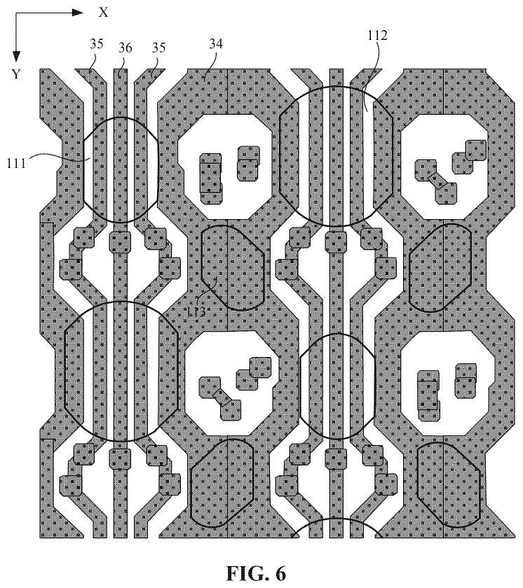

Optionally, at least one pixel circuit is formed on the substrate 10. Each pixel circuit is configured to generate a drive current to drive a light-emitting element connected to the each pixel circuit to emit light. The light-emitting element is located in an area where a first light-transmissive opening 100 is located. FIG. 5 is a pixel circuit diagram according to an embodiment of the present application. Referring to FIG. 4 and FIG. 5, each pixel circuit is formed of at least a thin-film transistor. The thin-film transistor includes at least a drive transistor Q1 and a first initialization transistor Q2. The first initialization transistor Q2 is connected between a first wire 31 and a light-emitting element. The first initialization transistor Q2 is configured to transmit a first initialization voltage Vref1 on the first wire 31 to the light-emitting element. The gate of the first initialization transistor Q2 is connected to a first scan line to respond to a first scan signal S1 output by the first scan line. The light-emitting element may be an OLED element.

The drive transistor Q1 is connected to a second wire 32. The drive transistor Q1 is configured to transmit a power voltage VDD on the second wire 32 to a light-emitting element to drive the light-emitting element to emit light.

The first wire 31 configured to transmit the first initialization voltage Vref1 and the second wire 32 configured to transmit the power voltage VDD are located in a conductive layer on the side of the light-emitting element facing the substrate 10 and are adjacent to the light-emitting element. Therefore, flatness of the conductive layer under each first light-transmissive opening 100 greatly affects subsequent preparation of light-emitting elements. In some embodiments, a first wire 31 is differentiated under different first light-transmissive openings 100 such that the conductive layer located under each first light-transmissive opening 100 to contain the first wire 31 is symmetrical, thereby reducing a film height difference of the pixel area corresponding to each first light-transmissive opening 100 and alleviating display color cast.

Referring to FIG. 5, each pixel circuit of this embodiment also includes a data write transistor Q3 and a compensation transistor Q4. The data write transistor Q3 is connected between a data line Data and the first electrode of the drive transistor Q1. The compensation transistor Q4 is connected between the second electrode of the drive transistor Q1 and the gate of the drive transistor Q1. The gate of the compensation transistor Q4 and the gate of the data write transistor Q3 are connected to a second scan line to respond to a second scan signal S2 transmitted on the second scan line.

Optionally, each pixel circuit also includes a first light emission control transistor Q5 and a second light emission control transistor Q6. The first light emission control transistor Q5 is connected between a second wire 32 and the first electrode of the drive transistor Q1. The second light emission control transistor Q6 is connected between the second electrode of the drive transistor Q1 and a light-emitting element. The gate of the first light emission control transistor Q5 and the gate of the second light emission control transistor Q6 are connected to a light emission control signal line to respond to a light emission control signal EM transmitted on the light emission control signal line. Each pixel circuit also includes a second initialization transistor Q7 and a storage capacitor C1. The second initialization transistor Q7 is connected to the gate of the drive transistor Q1 and configured to respond to a third scan signal on a third scan signal line connected to the gate to transmit a second initialization voltage Vref2 to the gate of the drive transistor Q1. The storage capacitor C1 is configured to store a gate voltage of the drive transistor Q1.

FIG. 6 is a plane view of another display panel according to an embodiment of the present application. Referring to FIG. 4 and FIG. 6, based on each previous embodiment, optionally, the conductive layers also include one or more fourth wires 34. The fourth wires 34 are disposed in a different layer than the first wires 31. The fourth wires 34 extend in a second direction Y. Fourth wires 34 are disposed on both sides (the left and the right) of each of some pixel units. For first light-transmissive openings 100 of part of the pixel units (for example, first light-transmissive openings 112 of second subpixels), overlapping portions between the vertical projection of fourth wires 34 on the substrate 10 and the vertical projection of the first light-transmissive opening 100 of a pixel unit on the substrate 10 are symmetrical about the vertical projection of the first light-transmissive opening 100 of the pixel unit on the substrate 10, that is, symmetrical about the Y-direction central axis of the vertical projection of the first light-transmissive opening 112 of the second subpixel on the substrate 10. The vertical projections of fourth wires 34 on the substrate 10 covers vertical projections of first light-transmissive openings 100 of a part of remaining pixel units on the substrate 10. For example, the vertical projections of fourth wires 34 on the substrate 10 covers vertical projections of first light-transmissive openings 113 of third subpixels on the substrate 10.

Optionally, on the two sides of a central axis of the vertical projection of the first light-transmissive opening 112 of a second subpixel on the substrate 10, the overlapping area between the vertical projection of a fourth wire 34 on one of the two sides of the central axis on the substrate 10 and the vertical projection of the first light-transmissive opening 112 of the second subpixel on the substrate 10 and the overlapping area between the vertical projection of a fourth wire 34 on another of the two sides of the central axis on the substrate 10 and the vertical projection of the first light-transmissive opening 112 of the second subpixel on the substrate 10 are the same. Optionally, the shortest distance between the vertical projection of the fourth wire 34 on one of the two sides of the central axis on the substrate 10 and the central axis of the vertical projection of the first light-transmissive opening 112 of the second subpixel on the substrate 10 and the shortest distance between the vertical projection of the fourth wire 34 on another of the two sides of the central axis on the substrate 10 and the central axis of the vertical projection of the first light-transmissive opening 112 of the second subpixel on the substrate 10 are the same. For details, see description about the first wires 31 and the second wires 32.

Each fourth wire 34 may be a power wire for transmitting a power voltage VDD. The second wires 32 are power wires extending in the first direction X. The fourth wires 34 are power wires extending in the second direction Y. The second wires 32 are located in a different conductive layer than the fourth wires 34. The fourth wires 34 are located on the side of the second wires 32 facing away from the substrate 10. Under the first light-transmissive opening 111 of a first subpixel, there is no fourth wire 34. Under the first light-transmissive opening 112 of a second subpixel, fourth wires 34 are located on two opposite sides of the first light-transmissive opening 112 and symmetrical about the central axis of the first light-transmissive opening 112. Under the first light-transmissive opening 113 of a third subpixel, a fourth wire 34 fully covers the area where the first light-transmissive opening 113 is located, that is, the vertical projection of the fourth wire 34 on the substrate 10 covers the vertical projection of the first light-transmissive opening 113 on the substrate 10.

Referring to FIG. 6, a conductive layer of the conductive layers, where the fourth wires 34 are located, also includes one or more fifth wires 35 and one or more sixth wires 36. The fifth wires 35 may be data lines Data shown in FIG. 5. The sixth wires 36 may be in-plane fan-out wires. The fifth wires 35 and the sixth wires 36 extend in the second direction Y. A sixth wire 36 is located between two adjacent fifth wires 35. Under the first light-transmissive opening 111 of a first subpixel, the vertical projections of fifth wires 35 on the substrate 10 are symmetrical about the central axis of the vertical projection of the first light-transmissive opening 111 on the substrate 10. Under the first light-transmissive opening 112 of a second subpixel, the vertical projections of fifth wires 35 on the substrate 10 are located on the two sides of the central axis of the vertical projection of the first light-transmissive opening 112 on the substrate 10, for example, the vertical projections of fifth wires 35 on the substrate 10 are symmetrical about the central axis of the vertical projection of the first light-transmissive opening 112 on the substrate 10. A sixth wire 36 is located on the central axis of the first light-transmissive opening 112 of a second subpixel. In the same column of pixel units, the central axis of the first light-transmissive opening 111 of a first subpixel coincides with the central axis of the first light-transmissive opening 112 of a second subpixel. In some embodiments, the film height difference between the left part and the right part (or the film height difference between the upper part and the lower part) of the pixel area corresponding to the first light-transmissive opening 100 of each subpixel is small so that display color cast is reduced.

Optionally, each conductive layer may be a metal layer, and each wire may be a metal wire.

Optionally, on the two sides of the central axis of the vertical projection of the corresponding first light-transmissive opening 100 on the substrate 10, the overlapping area between the vertical projection of a fifth wire 35 on one of the two sides of the central axis on the substrate 10 and the vertical projection of the corresponding first light-transmissive opening 100 on the substrate 10 and the overlapping area between the vertical projection of a fifth wire 35 on another of the two sides of the central axis on the substrate 10 and the vertical projection of the corresponding first light-transmissive opening 100 on the substrate 10 are the same. Optionally, the shortest distance between the vertical projection of the fifth wire 35 on one of the two sides of the central axis on the substrate 10 and the central axis of the vertical projection of the corresponding first light-transmissive opening 100 on the substrate 10 and the shortest distance between the vertical projection of the fifth wire 35 on another of the two sides of the central axis on the substrate 10 and the central axis of the vertical projection of the corresponding first light-transmissive opening 100 on the substrate 10 are the same. For details, see description about the first wires 31 and the second wires 32.

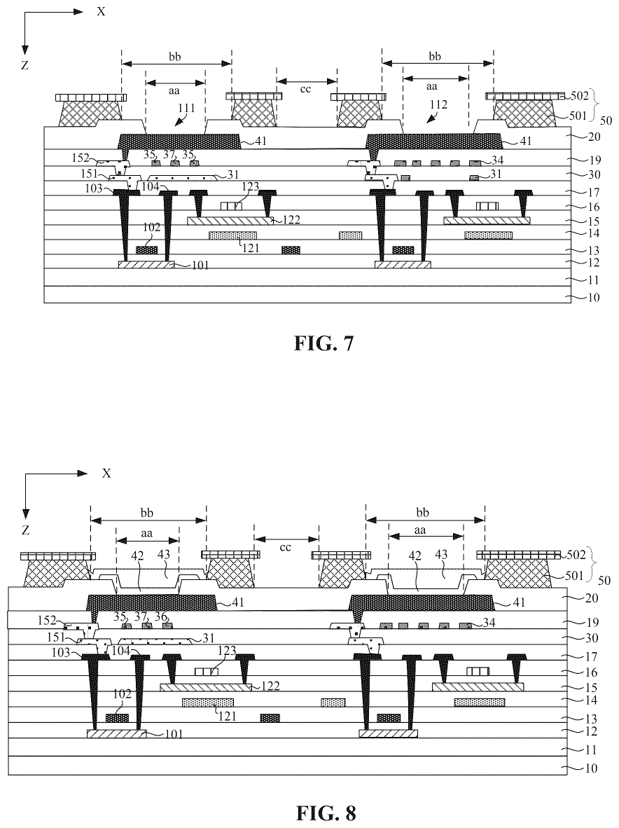

FIG. 7 is a section view of another display panel, a section view taken along section line AA′ of FIG. 1 to illustrate the structure of the display panel of FIG. 1, according to an embodiment of the present application. Referring to FIG. 1 to FIG. 7, the display panel includes a substrate 10 and a buffer layer 11 located on one side of the substrate 10. The buffer layer 11 may be formed of an inorganic material for protection and buffering. First active layers 101 and first gates 102 are successively disposed on the side of the buffer layer 11 facing away from the substrate 10. A first gate insulation layer 12 is disposed between the first active layers 101 and the first gates 102. The first gate insulation layer 12 covers the first active layers 101. The first gate insulation layer 12 contacts the buffer layer 11. The first gate insulation layer 12 is configured to insulate the first active layers 101 from the first gates 102. A capacitor dielectric layer 13 is disposed on the side of the first gates 102 facing away from the substrate 10. The capacitor dielectric layer 13 is configured to insulate the upper plates (not shown) of storage capacitors from the lower plates (not shown) of the storage capacitors. The lower plates of the capacitors may be disposed in the same layer as the first gates 102. A second interlayer insulation layer 16 is disposed on the side of the capacitor dielectric layer 13 facing away from the substrate 10. First sources 103 and first drains 104 are formed on the side of the second interlayer insulation layer 16 facing away from the substrate 10 and are connected to the first active layers 101 by vias. The first planarization layer 17 covers the first sources 103 and the first drains 104. First transition parts 151 and second transition parts 152 are disposed on the side of the first planarization layer 17 facing away from the substrate 10. A second planarization layer 30 is disposed on the first transition parts 151 and the second transition parts 152. The first transition parts 151 and the second transition parts 152 are configured to transit connections between conductive layers, avoiding opening deep holes in films. A third planarization layer 19 is disposed on the side of the second transition parts 152 facing away from the substrate 10.

The first active layers 101, the first gates 102, the first sources 103, and the first drains 104 form a pixel circuit layer. In some embodiments, the pixel circuit layer also includes second gates 121, second active layers 122, and third gates 123. The second active layers 122 are different from the first active layers 101. Each second active layer 122 is made of metal oxide, for example, indium gallium zinc oxide. Each first active layer 111 is made of low-temperature polycrystalline silicon.

The second gates 121 may be bottom gates located on the side of the capacitor dielectric layer 13 facing away from the substrate 10. The second active layers 122 are located on the side of a first interlayer insulation layer 14 facing away from the substrate 10. A second gate insulation layer 15 covers the second active layers 122. The third gates 123 are located on the side of the second gate insulation layer 15 facing away from the substrate 10. The second interlayer insulation layer 16 covers the third gates 123. The third gates 123 may be top gates.

The multiple conductive layers include a first conductive layer, a second conductive layer, a third conductive layer, a fourth conductive layer, and a fifth conductive layer that are stacked in sequence. Transistors of each pixel circuit are formed in the first conductive layer, the second conductive layer, and the third conductive. Optionally, the first gates 101 are located in the first conductive layer, the second gates 121 are located in the second conductive layer, the first sources 103 and the first drains 104 are located in the third conductive layer, the first transition parts 151 are located in the fourth conductive layer, and the second transition parts 152 are located in the fifth conductive layer.

Referring to FIG. 6 and FIG. 7, in some embodiments, the fourth conductive layer also includes one or more first wires 31, one or more second wires 32, and one or more third wires 33. The vertical projection of a first wire 31 on the substrate 10 overlaps the central area of the vertical projection of the first light-transmissive opening 111 of a first subpixel on the substrate 10. The vertical projection of a first wire 31 on the substrate 10 overlaps the edge area of the vertical projection of the first light-transmissive opening 112 of a second subpixel on the substrate 10. The vertical projection of a first wire 31 on the substrate 10 and the vertical projection of a second wire 32 on the substrate 10 are symmetrical about the central axis of the vertical projection of the first light-transmissive opening 112 of a second subpixel on the substrate 10. The vertical projection of a first wire 31 on the substrate 10 is located on the central axis of the vertical projection of the first light-transmissive opening 111 of a first subpixel on the substrate 10. Thus, the film flatness difference between the left part and the right part of each pixel area and/or the film height difference between the upper part and the lower part of each pixel area is reduced such that the film height difference between the left part and the right part of each pixel area and/or the film height difference between the upper part and the lower part of each pixel area caused by nonflatness of the fourth conductive layer is reduced so that color cast at a non-front viewing angle is reduced.

The fifth conductive layer also includes one or more fourth wires 34, one or more fifth wires 35, and one or more sixth wires 36. Under the first light-transmissive opening 111 of a first subpixel, the vertical projections of fifth wires 35 on the substrate 10 are symmetrical about the central axis of the vertical projection of the first light-transmissive opening 111 on the substrate 10. Under the first light-transmissive opening 112 of a second subpixel, the vertical projections of fifth wires 35 on the substrate 10 are symmetrical about the central axis of the vertical projection of the first light-transmissive opening 112 on the substrate 10. Under the first light-transmissive opening 112 of a second subpixel, the vertical projections of fourth wires 34 on the substrate 10 are symmetrical about the central axis of the vertical projection of the first light-transmissive opening 112 on the substrate 10. The vertical projection of a sixth wire 36 on the substrate 10 is located on the central axis of the vertical projection of the first light-transmissive opening 111 of a first subpixel on the substrate 10 and on the central axis of the vertical projection of the first light-transmissive opening 112 of a second subpixel on the substrate 10. Thus, the film height difference between the left part and the right part of the pixel area corresponding to the first light-transmissive opening 100 of each subpixel is small so that color cast is reduced.

Referring to FIG. 7, optionally, the display panel also includes first electrodes 41 and isolation structures 50. The first electrodes 41 are located on the side of the pixel definition layer 20 facing the substrate 10. Each first electrode 41 is exposed by a first light-transmissive opening. The isolation structures 50 are located on the side of the pixel definition layer 20 facing away from the substrate 10. Each isolation structure 50 has a second light-transmissive opening. The first light-transmissive opening and at least part of the pixel definition layer 20 are exposed by a second light-transmissive opening. For details about the isolation structure, see patents PCT/CN2023/134518, CN202310771124.9, CN202311499823.9, CN202310731471.9, CN202311686416.9, CN202310707183.X, CN202311764506.5, CN202310479495.X, CN202310771071.0, and CN202310759370.2.

Area aa is where a first light-transmissive opening is located. Area bb is where a second light-transmissive opening is located. A second light-transmissive opening is formed by being enclosed by the surface of an isolation structure 50 in contact with the pixel definition layer 20. Optionally, a second light-transmissive opening may be connected to a first light-transmissive opening, where the first light-transmissive opening is in the second light-transmissive opening, and the first light-transmissive opening and at least part of the pixel definition layer 20 are exposed by the second light-transmissive opening.

FIG. 8 is a section view of another display panel according to an embodiment of the present application. Referring to FIG. 8, based on the previous embodiments, the display panel also includes light-emitting function layers 42 and second electrodes 43. A light-emitting function layer 42 is located on the side of a first electrode 41 facing away from the substrate 10. A second electrode 43 is located on the side of a light-emitting function layer 42 facing away from the substrate 10. The second electrode 43 is located in a first light-transmissive opening and a second light-transmissive opening. The second electrode 43 is in contact with at least part of isolation structures 50.

A first electrode 41, a light-emitting function layer 42, and a second electrode 43 that are stacked form a light-emitting element. Light-emitting elements of different colors correspond to different light-emitting function layers 42. The second electrode 43 may be a cathode. The first electrode 41 may be an anode. The second electrodes 43 are separated by the isolation structures 50. Optionally, isolation structures 50 corresponding to light-emitting elements of different colors may be arranged separate and insulated from each other and second electrodes 43 corresponding to light-emitting elements of different colors may be arranged separate and insulated from each other so that each second electrode 43 can be controlled separately.

Optionally, the isolation structure 50 includes a conductive material, and a power voltage (a second power voltage VSS) may be transmitted to a second electrode 43 by an isolation structure 50.

Optionally, whether adjacent isolation structures 50 are arranged insulated from each other may be adjusted according to the arrangement of the pixel units. In an implementation of some embodiments, among at least the same row of pixel units, adjacent pixel units correspond to isolation structures 50 insulated from each other; and in the same pixel unit, a second electrode 43 is in contact with an isolation structure 50. Among the same column of pixel circuits, adjacent pixel units correspond to isolation structures 50 electrically connected to each other. For example, if one isolation structure 50 is disposed between two adjacent pixel units among the same column of pixel circuits, the second electrodes of the two adjacent pixel units are both connected to this isolation structure 50. Alternatively, isolation structures 50 corresponding to adjacent pixel units among the same column of pixel circuits are insulated from each other. These isolation structures are connected in the same manner as isolation structures 50 corresponding to adjacent pixel units among the same row of pixel units.

Optionally, the isolation structure 50 also has an isolation opening. The isolation opening is apart from the second light-transmissive opening. Area cc is where an isolation opening is located. The vertical projection of a light-emitting function layer 42 on the substrate 10 and the vertical projection of a second electrode 43 on the substrate 10 do not overlap the vertical projection of an isolation opening on the substrate 10. The vertical projection of an isolation opening on the substrate 10 does not overlap the vertical projection of a first light-transmissive opening on the substrate 10. That is, a light-emitting function layer 42 and a second electrode 43 are not located in an isolation opening, and an isolation opening and a first light-transmissive opening are not connected to each other.

Optionally, referring to FIG. 7 and FIG. 8, the isolation structure 50 includes a support portion 501 and a crown portion 502. The crown portion 502 is located on the side of the support portion 501 facing away from the substrate 10. The vertical projection of the support portion 501 on the substrate 10 falls into the vertical projection of the crown portion 502 on the substrate 10 so that the isolation structure 50 can isolate light-emitting function layers 42 of adjacent light-emitting elements from each other, thereby avoiding the problem of lateral current crosstalk. Moreover, the isolation structure 50 has eaves, so in a film deposition process, the light-emitting function layer 42 of the light-emitting element is formed by photoetching, not formed separately by using a precision mask, thereby saving costs.

Optionally, two isolation structures 50 may be disposed between adjacent pixel units, where the two isolation structures 50 are insulated from each other. In other embodiments, one isolation structure 50 may be disposed between adjacent pixel units, where this isolation structure 50 is split into two parts for insulating the second electrodes 43 of the adjacent pixel units from each other.

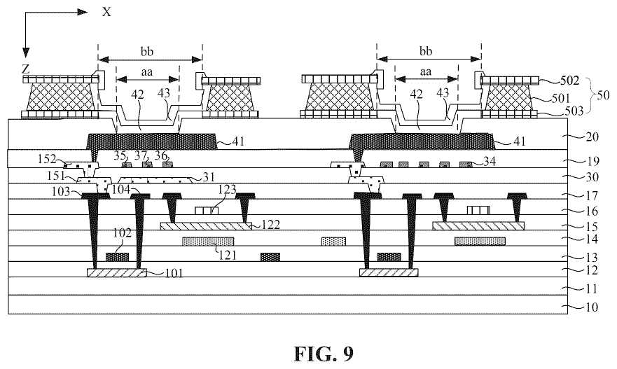

FIG. 9 is a section view of another display panel according to an embodiment of the present application. Referring to FIG. 9, based on each previous embodiment, optionally, the isolation structure 50 also includes a root portion 503. The root portion 503 is located on the side of the support portion 501 facing the substrate 10. The vertical projection of the support portion 501 on the substrate 10 is located in the vertical projection of the root portion 503 on the substrate 10.

The root portion 503 may include a conductive material. The root portion 503, the support portion 501, and the crown portion 502 are electrically connected in sequence. The isolation structure 50 is H-shaped such that at least part of the root portion 503 can be covered by a second electrode 43 so that electrical connection can be implemented between the second electrode 43, the support portion 501, and the root portion 503, increasing the base area between the second electrode 43 and the isolation structure 50 and ensuring the reliability of transmission of a second power voltage VSS through the isolation structure 50.

Optionally, the pixel definition layer 20 may also include recess portions. The isolation structure 50 may be disposed in a recess portion, reducing the overall film thickness.

In a panel preparation process, the second planarization layer 30 and the third planarization layer 19 are not thick enough to completely cover the flatness difference of each first wire 31 in pixel areas of the fourth conductive layer. Therefore, in some embodiments, a first wire 31 in pixel areas of the fourth conductive layer is differentiated such that the conductive layer where the first wire 31 is located is symmetrical in at least part of the pixel areas, thereby reducing a film height difference in each pixel area, alleviating display color cast, and improving the display effect.

Optionally, in another implementation of one or more embodiments, the display panel includes a substrate 10, a pixel definition layer 20, and conductive layers. The pixel definition layer 20 is located on one side of the substrate 10. The pixel definition layer 20 includes multiple first light-transmissive openings 100 that define pixel units. The conductive layers are disposed between the substrate 10 and the pixel definition layer 20.

The conductive layers include one or more first wires 31 and one or more second wires 32 that are disposed in a same conductive layer. At least one of following configurations is satisfied: the vertical projection of a first wire 31 on the substrate 10 being located on a central axis of a vertical projection of a first light-transmissive opening in at least part of the first light-transmissive openings 100 on the substrate 10; and the vertical projection of a first wire 31 on the substrate 10 and the vertical projection of a second wire 32 on the substrate being located on the two sides of a central axis of a vertical projection of a first light-transmissive opening in at least part of the first light-transmissive openings 100 on the substrate 10.

The solution of this embodiment can be combined with the solution of any previous embodiment. For the working principle of the solution of this embodiment, see relevant description in any previous embodiment. This embodiment has the same beneficial effects as any previous embodiment.

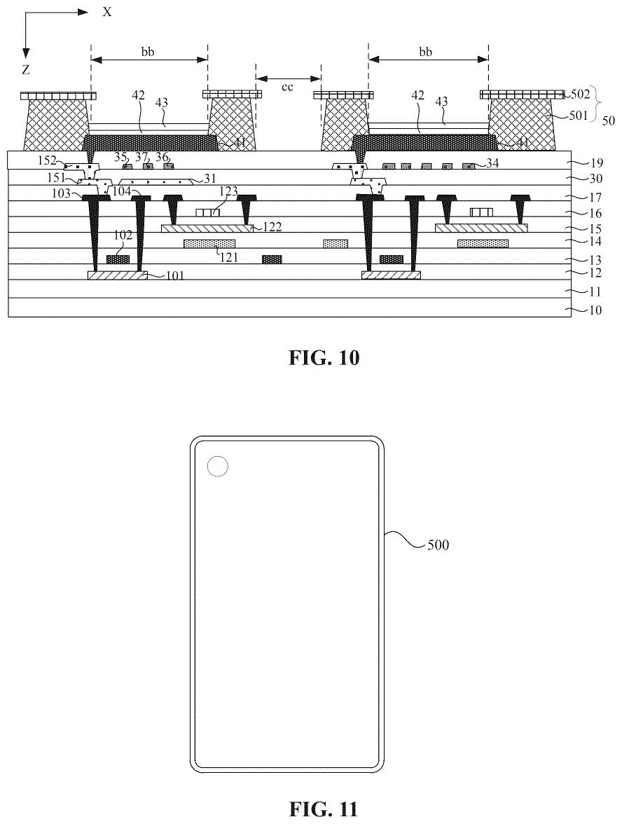

Optionally, in another implementation of one or more embodiments, the display panel may define pixel units by using isolation structures; thereby no pixel definition layer is required. FIG. 10 is a section view of another display panel according to an embodiment of the present application. Referring to FIG. 10, the display panel includes a substrate 10, isolation structures 50, and conductive layers. Each isolation structure 50 has a second light-transmissive opening. Second light-transmissive openings are in one-to-one correspondence with pixel units in the display panel. The conductive layers are disposed between the substrate 10 and the isolation structures 50.

The conductive layers include one or more first wires 31 and one or more second wires 32. At least one of following configurations is satisfied: the vertical projection of a first wire 31 on the substrate 10 being located on a central axis of a vertical projection of a second light-transmissive opening in at least part of the second light-transmissive openings on the substrate 10; and the vertical projection of a first wire 31 on the substrate 10 and the vertical projection of a second wire 32 on the substrate being located on the two sides of a central axis of a vertical projection of a second light-transmissive opening in at least part of the second light-transmissive openings on the substrate 10.

With no pixel definition layer, the solution of this embodiment can be combined with the solution of any previous embodiment (the first light-transmissive openings are replaced with the second light-transmissive openings). For the working principle of the solution of this embodiment, see relevant description in any previous embodiment. This embodiment has the same beneficial effects as any previous embodiment.

Optionally, an embodiment of the present application provides a display device. The display device includes the display panel of any embodiment of the present application. FIG. 11 is a diagram illustrating the structure of a display device according to an embodiment of the present application. The display device 500 may be a mobile phone of FIG. 11 or may be an electronic device such as a tablet computer, a mobile phone, a watch, a wearable device, a vehicle-mounted display, a camera display, a television screen, or a computer screen. The display device includes the display panel of any embodiment of the present application; therefore, the display device of this embodiment of the present application has the beneficial effects described in any embodiment of the present application.

It is to be understood that various forms of processes shown above may be adopted with steps reordered, added or deleted. For example, the steps described in the present application may be performed in parallel, sequentially or in different sequences, as long as the desired results of the technical solutions of the present application can be achieved, and no limitation is imposed herein.

The preceding embodiments do not limit the scope of the present application. It is to be understood by those skilled in the art that various modifications, combinations, sub-combinations, and substitutions may be performed according to design requirements and other factors. Any modification, equivalent substitution, improvement or the like made within the spirit and principle of the present application is within the scope of the present application.

What is claimed is:

1. A display panel, comprising:
a substrate;
a pixel definition layer located on one side of the substrate, wherein the pixel definition layer comprises a plurality of first light-transmissive openings that define pixel units; and
conductive layers disposed between the substrate and the pixel definition layer;
wherein the conductive layers comprise a first wire, and overlapping positions between a vertical projection of the first wire on the substrate and vertical projections of at least part of the plurality of first light-transmissive openings on the substrate are different, wherein an overlapping position of the overlapping positions is a position of an overlapping portion relative to a vertical projection of a corresponding first light-transmissive opening on the substrate, and the overlapping portion is an overlap between the vertical projection of the first wire on the substrate and the vertical projection of the corresponding first light-transmissive opening on the substrate.

2. The display panel of claim 1, wherein the first wire comprises a body portion and a branch portion, the branch portion comprises a first connection subportion and a second connection subportion, the second connection subportion is connected to the body portion by the first connection subportion, the body portion and the second connection subportion extend in a first direction, the first connection subportion extends in a second direction intersecting the first direction, and the first direction and the second direction are perpendicular to a thickness direction of the substrate; and
a vertical projection of the second connection subportion on the substrate overlaps central areas of vertical projections of at least part of the plurality of first light-transmissive openings on the substrate, and a vertical projection of the body portion on the substrate overlaps edge areas of vertical projections of at least part of the plurality of first light-transmissive openings on the substrate; or a vertical projection of the body portion on the substrate overlaps central areas of vertical projections of at least part of the plurality of first light-transmissive openings on the substrate, and a vertical projection of the second connection subportion on the substrate overlaps edge areas of vertical projections of at least part of the plurality of first light-transmissive openings on the substrate.

3. The display panel of claim 1, wherein the pixel units comprise different types of subpixels, and overlapping positions between the vertical projection of the first wire on the substrate and vertical projections of first light-transmissive openings corresponding to different types of subpixels on the substrate are different;
sizes of the first light-transmissive openings corresponding to the different types of subpixels are different; and
overlapping positions between the vertical projection of the first wire on the substrate and vertical projections of first light-transmissive openings corresponding to the same type of subpixels on the substrate are the same.

4. The display panel of claim 3, wherein the pixel units comprise a first subpixel and a second subpixel, and the first subpixel and the second subpixel have different emission colors;
in an extension direction of the first wire, the first subpixel alternates with the second subpixel, and an opening size of a first light-transmissive opening of the second subpixel is greater than an opening size of a first light-transmissive opening of the first subpixel; and
the vertical projection of the first wire on the substrate overlaps a central area of a vertical projection of the first light-transmissive opening of the first subpixel on the substrate, and the vertical projection of the first wire on the substrate overlaps an edge area of a vertical projection of the first light-transmissive opening of the second subpixel on the substrate.

5. The display panel of claim 4, wherein the pixel units further comprise a third subpixel, and the vertical projection of the first wire on the substrate does not overlap a vertical projection of a first light-transmissive opening of the third subpixel on the substrate; and
the first subpixel is a red subpixel, the second subpixel is a blue subpixel, the third subpixel is a green subpixel, the vertical projection of the first wire on the substrate is located on a central axis of the vertical projection of the first light-transmissive opening of the first subpixel on the substrate, and the vertical projection of the first wire on the substrate is located on one side of a central axis of the vertical projection of the first light-transmissive opening of the second subpixel on the substrate.

6. The display panel of claim 5, wherein the conductive layers further comprise a second wire, and the second wire and the first wire are disposed in a same conductive layer; and
a vertical projection of the second wire on the substrate overlaps the edge area of the vertical projection of the first light-transmissive opening of the second subpixel on the substrate, and the vertical projection of the second wire on the substrate and the vertical projection of the first wire on the substrate are located on two sides of the central axis of the vertical projection of the first light-transmissive opening of the second subpixel on the substrate.

7. The display panel of claim 6, wherein on the two sides of the central axis of the vertical projection of the first light-transmissive opening of the second subpixel on the substrate, an overlapping area between the vertical projection of the first wire on the substrate and the vertical projection of the first light-transmissive opening of the second subpixel on the substrate and an overlapping area between the vertical projection of the second wire on the substrate and the vertical projection of the first light-transmissive opening of the second subpixel on the substrate are the same;
a shortest distance between the vertical projection of the first wire on the substrate and the central axis of the vertical projection of the first light-transmissive opening of the second subpixel on the substrate is the same as a shortest distance between the vertical projection of the second wire on the substrate and the central axis of the vertical projection of the first light-transmissive opening of the second subpixel on the substrate;
at the first light-transmissive opening of the second subpixel, the vertical projection of the second wire on the substrate and the vertical projection of the first wire on the substrate are symmetrical about the central axis of the vertical projection of the first light-transmissive opening of the second subpixel on the substrate; and
an extension direction of the second wire is the same as the extension direction of the first wire.

8. The display panel of claim 6, wherein the conductive layers further comprise a third wire, and a vertical projection of the third wire on the substrate and the vertical projection of the second wire on the substrate are located on two sides of a central axis of the vertical projection of the first light-transmissive opening of the third subpixel on the substrate.

9. The display panel of claim 8, wherein on the two sides of the central axis of the vertical projection of the first light-transmissive opening of the third subpixel on the substrate, an overlapping area between the vertical projection of the second wire on the substrate and the vertical projection of the first light-transmissive opening of the third subpixel on the substrate and an overlapping area between the vertical projection of the third wire on the substrate and the vertical projection of the first light-transmissive opening of the third subpixel on the substrate are the same;
a shortest distance between the vertical projection of the second wire on the substrate and the central axis of the vertical projection of the first light-transmissive opening of the third subpixel on the substrate is the same as a shortest distance between the vertical projection of the third wire on the substrate and the central axis of the vertical projection of the first light-transmissive opening of the third subpixel on the substrate;
at the first light-transmissive opening of the third subpixel, the vertical projection of the second wire on the substrate and the vertical projection of the third wire on the substrate are symmetrical about the central axis of the vertical projection of the first light-transmissive opening of the third subpixel on the substrate; and
the third wire and the first wire are disposed in a same conductive layer, and an extension direction of the third wire is the same as the extension direction of the second wire.

10. The display panel of claim 6, wherein at least one pixel circuit is formed on the substrate, each of the at least one pixel circuit comprises a drive transistor and a first initialization transistor, the first initialization transistor is connected between the first wire and a light-emitting element, and the first initialization transistor is configured to transmit a first initialization voltage on the first wire to the light-emitting element; and
the drive transistor is connected to the second wire, and the drive transistor is configured to transmit a power voltage on the second wire to the light-emitting element to drive the light-emitting element to emit light.

11. The display panel of claim 4, wherein the conductive layers further comprise fourth wires, and the fourth wires and the first wire are disposed in different conductive layers; and
vertical projections of fourth wires on the substrate are located on two sides of another central axis of the vertical projection of the first light-transmissive opening of the second subpixel on the substrate.

12. The display panel of claim 11, wherein on the two sides of the another central axis of the vertical projection of the first light-transmissive opening of the second subpixel on the substrate, an overlapping area between a vertical projection of a fourth wire on one of the two sides of the another central axis on the substrate and the vertical projection of the first light-transmissive opening of the second subpixel on the substrate and an overlapping area between a vertical projection of a fourth wire on another of the two sides of the another central axis on the substrate and the vertical projection of the first light-transmissive opening of the second subpixel on the substrate are the same;
a shortest distance between the vertical projection of the fourth wire on the one of the two sides of the another central axis on the substrate and the another central axis of the vertical projection of the first light-transmissive opening of the second subpixel on the substrate and a shortest distance between the vertical projection of the fourth wire on the another of the two sides of the another central axis on the substrate and the another central axis of the vertical projection of the first light-transmissive opening of the second subpixel on the substrate are the same;
overlapping portions between the vertical projections of the fourth wires on the substrate and the vertical projection of the first light-transmissive opening of the second subpixel on the substrate are symmetrical about the another central axis of the vertical projection of the first light-transmissive opening of the second subpixel on the substrate;
a vertical projection of a fourth wire on the substrate covers the vertical projection of the first light-transmissive opening of the third subpixel on the substrate;
a vertical projection of a fourth wire on the substrate does not overlap the vertical projection of the first light-transmissive opening of the first subpixel on the substrate;
the fourth wires are located on a side of the first wire facing away from the substrate;
the conductive layers comprise a first conductive layer, a second conductive layer, a third conductive layer, a fourth conductive layer, and a fifth conductive layer that are stacked; and
transistors of a pixel circuit are formed in the first conductive layer, the second conductive layer, and the third conductive layer; and the first wire is located in the fourth conductive layer, and the fourth wires are located in the fifth conductive layer.

13. The display panel of claim 11, wherein the conductive layers further comprise fifth wires, and the fifth wires and the fourth wires are disposed in a same conductive layer; and
the fifth wires are located on a side of first light-transmissive openings of the first subpixel and the second subpixel facing the substrate, and vertical projections of the fifth wires on the substrate are located on two sides of another central axis of a vertical projection of a corresponding first light-transmissive opening on the substrate.

14. The display panel of claim 13, wherein on the two sides of the another central axis of the vertical projection of the corresponding first light-transmissive opening on the substrate, an overlapping area between a vertical projection of a fifth wire on one of the two sides of the another central axis on the substrate and the vertical projection of the corresponding first light-transmissive opening on the substrate and an overlapping area between a vertical projection of a fifth wire on another of the two sides of the another central axis on the substrate and the vertical projection of the corresponding first light-transmissive opening on the substrate are the same;
a shortest distance between the vertical projection of the fifth wire on the one of the two sides of the another central axis on the substrate and the another central axis of the vertical projection of the corresponding first light-transmissive opening on the substrate and a shortest distance between the vertical projection of the fifth wire on the another of the two sides of the another central axis on the substrate and the another central axis of the vertical projection of the corresponding first light-transmissive opening on the substrate are the same;
the vertical projections of the fifth wires on the substrate are symmetrical about the another central axis of the vertical projection of the corresponding first light-transmissive opening on the substrate;
an extension direction of the fifth wires is the same as an extension direction of the fourth wires;
the conductive layers further comprise a sixth wire, and the sixth wire and the fourth wires are disposed in a same layer; and
a vertical projection of the sixth wire on the substrate is located on the another central axis of the vertical projection of the corresponding first light-transmissive opening on the substrate.

15. The display panel of claim 1, wherein the display panel further comprises first electrodes and isolation structures, the first electrodes are located on a side of the pixel definition layer facing the substrate, and the first electrodes are exposed by the plurality of first light-transmissive openings; and
the isolation structures are located on a side of the pixel definition layer facing away from the substrate, the isolation structures are provided with a plurality of second light-transmissive openings, and a first light-transmissive opening and at least part of the pixel definition layer are exposed by a second light-transmissive opening of the plurality of second light-transmissive openings.

16. The display panel of claim 15, wherein the display panel further comprises light-emitting function layers and second electrodes, the light-emitting function layers are located on a side of the first electrodes facing away from the substrate, the second electrodes are located on a side of the light-emitting functions layers facing away from the substrate, and a second electrode of the second electrodes is located in a first light-transmissive opening and a second light-transmissive opening; and
the second electrode is in contact with at least part of the isolation structures.

17. The display panel of claim 16, wherein at least part of adjacent second electrodes are insulated from each other;
wherein the plurality of first light-transmissive openings are arrayed, at least part of the isolation structures are disposed around a first light-transmissive opening, isolation structures corresponding to adjacent pixel units in at least a same row of the pixel units of the display panel are insulated from each other, and a second electrode and an isolation structure in a same pixel unit of the pixel units of the display panel contact each other;
isolation structures corresponding to adjacent pixel units in a same column of the pixel units of the display panel are insulated from each other or connected to each other; and
an isolation structure of the isolation structures comprises a conductive material, and the isolation structure is further configured to transmit a power voltage to a second electrode of the second electrodes.

18. The display panel of claim 15, wherein an isolation structure of the isolation structures comprises a support portion and a crown portion, the crown portion is located on a side of the support portion facing away from the substrate, and a vertical projection of the support portion on the substrate is located in a vertical projection of the crown portion on the substrate;
the isolation structure further comprises a root portion, the root portion is located on a side of the support portion facing the substrate, and the vertical projection of the support portion on the substrate is located in a vertical projection of the root portion on the substrate;
the root portion comprises a conductive material; and
the isolation structures are further provided with isolation openings, the pixel definition layer is exposed by the isolation openings, and the isolation openings and the second light-transmissive openings are spaced apart.

19. A display panel, comprising:
a substrate;
a pixel definition layer located on one side of the substrate, wherein the pixel definition layer comprises a plurality of first light-transmissive openings that define pixel units; and
conductive layers disposed between the substrate and the pixel definition layer,
wherein the conductive layers comprise a first wire and a second wire, and at least one of following configurations is satisfied: a vertical projection of the first wire on the substrate being located on a central axis of a vertical projection of a first light-transmissive opening in at least part of the plurality of first light-transmissive openings on the substrate; and a vertical projection of the first wire on the substrate and a vertical projection of the second wire on the substrate being located on two sides of a central axis of a vertical projection of a first light-transmissive opening in at least part of the plurality of first light-transmissive openings on the substrate.

20. The display panel of claim 19, wherein the first wire comprises a body portion and a branch portion, the branch portion comprises a first connection subportion and a second connection subportion, the second connection subportion is connected to the body portion by the first connection subportion, the body portion and the second connection subportion extend in a first direction, the first connection subportion extends in a second direction intersecting the first direction, and the first direction and the second direction are perpendicular to a thickness direction of the substrate, and a vertical projection of the body portion on the substrate overlaps central areas of vertical projections of at least part of the plurality of first light-transmissive openings on the substrate; and
a vertical projection of the second connection subportion on the substrate overlaps edge areas of vertical projections of at least part of the plurality of first light-transmissive openings on the substrate; or a vertical projection of the second connection subportion on the substrate overlaps central areas of vertical projections of at least part of the plurality of first light-transmissive openings on the substrate, and a vertical projection of the body portion on the substrate overlaps edge areas of vertical projections of at least part of the plurality of first light-transmissive openings on the substrate.

21. The display panel of claim 19, wherein the pixel units comprise a first subpixel and a second subpixel, and the first subpixel and the second subpixel have different emission colors;
the vertical projection of the first wire on the substrate is located on a central axis of a vertical projection of a first light-transmissive opening of the first subpixel on the substrate, and the vertical projection of the second wire on the substrate and the vertical projection of the first wire on the substrate are located on two sides of the central axis of the vertical projection of the first light-transmissive opening of the second subpixel on the substrate;
on the two sides of the central axis of the vertical projection of the first light-transmissive opening of the second subpixel on the substrate, an overlapping area between the vertical projection of the first wire on the substrate and the vertical projection of the first light-transmissive opening of the second subpixel on the substrate and an overlapping area between the vertical projection of the second wire on the substrate and the vertical projection of the first light-transmissive opening of the second subpixel on the substrate are the same;
a shortest distance between the vertical projection of the first wire on the substrate and the central axis of the vertical projection of the first light-transmissive opening of the second subpixel on the substrate is the same as a shortest distance between the vertical projection of the second wire on the substrate and the central axis of the vertical projection of the first light-transmissive opening of the second subpixel on the substrate;
at the first light-transmissive opening of the second subpixel, the vertical projection of the second wire on the substrate and the vertical projection of the first wire on the substrate are symmetrical about the central axis of the vertical projection of the first light-transmissive opening of the second subpixel on the substrate; the first wire and the second wire are arranged in a same conductive layer;
the pixel units further comprise a third subpixel, and the vertical projection of the first wire on the substrate does not overlap a vertical projection of a first light-transmissive opening of the third subpixel on the substrate; the conductive layers further comprise a third wire, and a vertical projection of the third wire on the substrate and the vertical projection of the second wire on the substrate are located on two sides of a central axis of the vertical projection of the first light-transmissive opening of the third subpixel on the substrate;
on the two sides of the central axis of the vertical projection of the first light-transmissive opening of the third subpixel on the substrate, an overlapping area between the vertical projection of the second wire on the substrate and the vertical projection of the first light-transmissive opening of the third subpixel on the substrate and an overlapping area between the vertical projection of the third wire on the substrate and the vertical projection of the first light-transmissive opening of the third subpixel on the substrate are the same;
a shortest distance between the vertical projection of the second wire on the substrate and the central axis of the vertical projection of the first light-transmissive opening of the third subpixel on the substrate is the same as a shortest distance between the vertical projection of the third wire on the substrate and the central axis of the vertical projection of the first light-transmissive opening of the third subpixel on the substrate; and
at the first light-transmissive opening of the third subpixel, the vertical projection of the second wire on the substrate and the vertical projection of the third wire on the substrate are symmetrical about the central axis of the vertical projection of the first light-transmissive opening of the third subpixel on the substrate.

22. The display panel of claim 19, wherein the display panel further comprises first electrodes and isolation structures, the first electrodes are located on a side of the pixel definition layer facing the substrate, and the first electrodes are exposed by the plurality of first light-transmissive openings;
the isolation structures are located on a side of the pixel definition layer facing away from the substrate, the isolation structures are provided with a plurality of second light-transmissive openings, and a first light-transmissive opening and at least part of the pixel definition layer are exposed by a second light-transmissive opening of the plurality of second light-transmissive openings;
the display panel further comprises light-emitting function layers and second electrodes, the light-emitting function layers are located on a side of the first electrodes facing away from the substrate, the second electrodes are located on a side of the light-emitting function layers facing away from the substrate, and a second electrode of the second electrodes is located in a first light-transmissive opening and a second light-transmissive opening; and
the second electrode is in contact with at least part of the isolation structures.

23. A display panel, comprising:
a substrate;
isolation structures located on one side of the substrate, wherein the isolation structures comprise a plurality of second light-transmissive openings, and the plurality of second light-transmissive openings are in one-to-one correspondence with pixel units in the display panel; and
conductive layers disposed between the substrate and the isolation structures,
wherein the conductive layers comprise a first wire and a second wire, and at least one of following configurations is satisfied: a vertical projection of the first wire on the substrate being located on a central axis of a vertical projection of a second light-transmissive opening in at least part of the second light-transmissive openings on the substrate; and a vertical projection of the first wire on the substrate and a vertical projection of the second wire on the substrate being located on two sides of a central axis of a vertical projection of a second light-transmissive opening in at least part of the second light-transmissive openings on the substrate.

24. The display panel of claim 23, wherein the first wire comprises a body portion and a branch portion, the branch portion comprises a first connection subportion and a second connection subportion, the second connection subportion is connected to the body portion by the first connection subportion, the body portion and the second connection subportion extend in a first direction, the first connection subportion extends in a second direction intersecting the first direction, and the first direction and the second direction are perpendicular to a thickness direction of the substrate;
and a vertical projection of the body portion on the substrate overlaps central areas of vertical projections of at least part of the second light-transmissive openings on the substrate, and a vertical projection of the second connection subportion on the substrate overlaps edge areas of vertical projections of at least part of the second light-transmissive openings on the substrate; or a vertical projection of the second connection subportion on the substrate overlaps central areas of vertical projections of at least part of the second light-transmissive openings on the substrate, and a vertical projection of the body portion on the substrate overlaps edge areas of vertical projections of at least part of the second light-transmissive openings on the substrate.

25. The display panel of claim 23, wherein the pixel units comprise a first subpixel and a second subpixel, and the first subpixel and the second subpixel have different emission colors;
the vertical projection of the first wire on the substrate is located on a central axis of a vertical projection of a second light-transmissive opening of the first subpixel on the substrate, and the vertical projection of the second wire on the substrate and the vertical projection of the first wire on the substrate are located on two sides of the central axis of the vertical projection of the second light-transmissive opening of the second subpixel on the substrate;
on the two sides of the central axis of the vertical projection of the second light-transmissive opening of the second subpixel on the substrate, an overlapping area between the vertical projection of the first wire on the substrate and the vertical projection of the second light-transmissive opening of the second subpixel on the substrate and an overlapping area between the vertical projection of the second wire on the substrate and the vertical projection of the second light-transmissive opening of the second subpixel on the substrate are the same;
a shortest distance between the vertical projection of the first wire on the substrate and the central axis of the vertical projection of the second light-transmissive opening of the second subpixel on the substrate is the same as a shortest distance between the vertical projection of the second wire on the substrate and the central axis of the vertical projection of the second light-transmissive opening of the second subpixel on the substrate;
the first wire and the second wire are arranged in a same conductive layer;
the pixel units further comprise a third subpixel, and the vertical projection of the first wire on the substrate does not overlap a vertical projection of a second light-transmissive opening of the third subpixel on the substrate;
the conductive layers further comprise a third wire, and a vertical projection of the third wire on the substrate and the vertical projection of the second wire on the substrate are located on two sides of a central axis of the vertical projection of the second light-transmissive opening of the third subpixel on the substrate;
on the two sides of the central axis of the vertical projection of the second light-transmissive opening of the third subpixel on the substrate, an overlapping area between the vertical projection of the second wire on the substrate and the vertical projection of the second light-transmissive opening of the third subpixel on the substrate and an overlapping area between the vertical projection of the third wire on the substrate and the vertical projection of the second light-transmissive opening of the third subpixel on the substrate are the same;
a shortest distance between the vertical projection of the second wire on the substrate and the central axis of the vertical projection of the second light-transmissive opening of the third subpixel on the substrate is the same as a shortest distance between the vertical projection of the third wire on the substrate and the central axis of the vertical projection of the second light-transmissive opening of the third subpixel on the substrate; and
at the second light-transmissive opening of the third subpixel, the vertical projection of the second wire on the substrate and the vertical projection of the third wire on the substrate are symmetrical about the central axis of the vertical projection of the second light-transmissive opening of the third subpixel on the substrate.
